(19) United States
(12) Patent Application Publication
(10) Pub. No.: US 2019/0302555 A1
(43) Pub. Date: Oct. 3, 2019

(54) ARRAY SUBSTRATE AND DISPLAY PANEL

(71) Applicant: Wuhan China Star Optoelectronics Technology Co., Ltd., Wuhan (CN)

(72) Inventor: Yuejun TANG, Wuhan (CN)

(21) Appl. No.: 16/072,518

(22) PCT Filed: Apr. 25, 2018
(86) PCT No.: PCT/CN2018/084368

§ 371 Date: Jul. 25, 2018

(30) Foreign Application Priority Data
Mar. 28, 2018 (CN) 201810266117.2

(51) Int. Cl. G02F 1/1362; H01L 27/12; G02F 1/1343; G02F 1/1333; G06F 3/044; G06F 3/041

(52) U.S. Cl. CPC G02F 1/136286; H01L 27/1214; G02F 1/134309; G02F 1/13338; G06F 2203/04107; G06F 3/0412; G02F 2201/121; G02F 2201/123; G06F 3/044

(57) ABSTRACT

An array substrate and a display panel are provided. The array substrate includes a first common electrode layer, a pixel electrode layer, and wires. The first common electrode layer includes at least two first common electrode plates, and gaps are formed between corresponding two of the first common electrode plates adjacent to each other. The wires are located on one side of the first common electrode layer, and the wires are disposed corresponding to the gaps.

### FIELD OF INVENTION

The present disclosure relates to a technical field of displays, and more particularly to an array substrate and a display panel.

### BACKGROUND OF INVENTION

As an input medium, now a touch screen is the simplest, most convenient and natural human-computer interaction method. Liquid crystals are increasingly used in display panels because of the fine electrical controllability thereof. Liquid crystal displays (LCDs) are a type of widely-used flat panel displays, which adjusts an intensity of a backlight light field mainly through liquid crystal switches, so as to display images. An LCD display device includes thin film transistor (TFT) devices. That is, a TFT-LCD is a thin film field-effect transistor liquid crystal display. Each liquid crystal pixel of the display device is driven by a thin film transistor integrated therebehind, so that the display device has characteristics: high reaction speed, high brightness, high contrast, small size, low power consumption, no radiation, etc., and has acquired a leading position in the current market of displays. Therefore, the touch screen is integrated in the liquid crystal display panel to form various electronic products, such as mobile phones, laptop computers, MP3/MP4, etc.

FIG. 1 shows a structural view of an arrangement of touch electrodes and touch wires of an in-cell touch display panel in a prior art. Because touch electrodes 101 are formed by patterning a common electrode plate, there is no common electrode at demarcations between the touch electrodes 101. In order to reduce the loading of a touch chip 104 and to prevent a problem that a touch signal returning to the touch chip 104 is delayed, a portion of each touch electrode corresponding to a touch wire usually needs to be hollowed out (the hollowed out portion is not shown in the figure), so as to reduce a capacitance of the touch wire 102 and each touch electrode.

Furthermore, the touch wires include touch wires for driving electrodes and touch wires which are extensions and useless. When a touch wire is applied with a voltage, a coupling capacitance is formed between the touch wire and the common electrode plate, so that the touch control effect is influenced. At the same time, at the demarcations between the touch electrodes, because there is no corresponding common electrode to provide a voltage, the liquid crystal molecules will be influenced by data line signals or scan line signals so that an unwanted spin occurs, causing an optical problem of light leakage or low contrast at a large viewing angle, resulting in displaying of the display panel being abnormal.

### SUMMARY OF INVENTION

The present disclosure provides an array substrate and a display panel, so as to solve the technical problem of light leakage or low contrast at a large viewing angle.

For solving the above-mentioned technical problem, the present disclosure provides technical solutions as follows.

The present disclosure provides an array substrate, wherein the array substrate comprises:

a first common electrode layer comprising at least two first common electrode plates, wherein gaps are formed between corresponding two of the first common electrode plates adjacent to each other;
a pixel electrode layer disposed opposite to the first common electrode layer; and
wires located on one side of the first common electrode layer, wherein the wires are disposed corresponding to the gaps;
wherein the wires comprise first wires and second wires; the gaps comprise horizontal gaps and vertical gaps; the first wires and the second wires are disposed above or below the horizontal gaps, the vertical gaps, or the first common electrode plates;
wherein, when a display panel is in a display state, the first common electrode plates of the first common electrode layer and the pixel electrode layer are configured to drive liquid crystals, and the wires are configured to be provided with a first voltage to eliminate an interference of an electric field on the liquid crystals corresponding to the gaps; and when the display panel is in a touch state, the first common electrode plates of the first common electrode layer are configured to output a touch signal according to a touch operation.

According to one preferable embodiment of the present disclosure, the first wires and the second wires are manufactured in one same mask, and the first wires and the second wires do not intersect each other; and

one end of one of the first wires is connected to one of the first common electrode plates through a via, and the other end of the one of the first wires is connected to a touch chip of the display panel.

According to one preferable embodiment of the present disclosure, a recess is disposed in one of the first common electrode plates corresponding to one of the first wires or one of the second wires.

According to one preferable embodiment of the present disclosure, the second wires comprise horizontal second wires and vertical second wires; and

the number of the horizontal second wires or the vertical second wires is equal to the number of the first common electrode plates in each of columns of the first common electrode plates.

According to one preferable embodiment of the present disclosure, each of the horizontal second wires is electrically connected to one of the vertical second wires, and each of the vertical second wires is electrically connected to one of the horizontal second wires.

According to one preferable embodiment of the present disclosure, each of the horizontal second wires over each of the columns of the first common electrode plates is electrically connected to one of the vertical second wires, and each of the vertical second wires over each of the columns of the first common electrode plates is electrically connected to one of the horizontal second wires.

According to one preferable embodiment of the present disclosure, a portion of the first wires has corresponding U-turn first wires, and a total length of each of the first wires is equal to each other.

According to one preferable embodiment of the present disclosure, a portion of the first wires has corresponding parallel first wires, and a resistance of each of the first wires is equal to each other.

The present disclosure further provides a display panel, wherein the display panel comprises the array substrate.

The present disclosure further provides an array substrate, wherein the array substrate comprises:

a first common electrode layer comprising at least two first common electrode plates, wherein gaps are formed between corresponding two of the first common electrode plates adjacent to each other;
a pixel electrode layer disposed opposite to the first common electrode layer; and
wires located on one side of the first common electrode layer, wherein the wires are disposed corresponding to the gaps;
wherein, when a display panel is in a display state, the first common electrode plates of the first common electrode layer and the pixel electrode layer are configured to drive liquid crystals, and the wires are configured to be provided with a first voltage to eliminate an interference of an electric field on the liquid crystals corresponding to the gaps; and when the display panel is in a touch state, the first common electrode plates of the first common electrode layer are configured to output a touch signal according to a touch operation.

According to one preferable embodiment of the present disclosure, the wires comprise first wires and second wires;

the first wires and the second wires are manufactured in one same mask, and the first wires and the second wires do not intersect each other; and
one end of one of the first wires is connected to one of the first common electrode plates through a via, and the other end of the one of the first wires is connected to a touch chip of the display panel.

According to one preferable embodiment of the present disclosure, the second wires comprise horizontal second wires and vertical second wires; and

the number of the horizontal second wires or the vertical second wires is equal to the number of the first common electrode plates in each of columns of the first common electrode plates.

According to one preferable embodiment of the present disclosure, each of the horizontal second wires is electrically connected to one of the vertical second wires, and each of the vertical second wires is electrically connected to one of the horizontal second wires.

According to one preferable embodiment of the present disclosure, each of the horizontal second wires over each of the columns of the first common electrode plates is electrically connected to one of the vertical second wires, and each of the vertical second wires over each of the columns of the first common electrode plates is electrically connected to one of the horizontal second wires.

According to one preferable embodiment of the present disclosure, a portion of the first wires has corresponding U-turn first wires, and a total length of each of the first wires is equal to each other.

According to one preferable embodiment of the present disclosure, a portion of the first wires has corresponding parallel first wires, and a resistance of each of the first wires is equal to each other.

The beneficial effects of the present disclosure are that: in the present disclosure, wires are disposed on one side of the first common electrode plates adjacent to each other. The wires are used to be provided with a first voltage to eliminate an interference of the electric field on the liquid crystals corresponding to the gaps, so as to improve the display effect of the display panel. Furthermore, parallel or U-turn first wires are provided, so that the resistance value of each first wire is equal or similar, thereby improving the touch sensitivity of the display panel.

### DESCRIPTION OF DRAWINGS

In order to more clearly illustrate the embodiments or the prior art technical solutions, the embodiment is simply described with needed accompanying drawings. The following description the drawings are merely some embodiments of the present disclosure. Those of ordinary skill in the art, without inventive efforts, can derive other drawings from these drawings.

FIG. 1 is a structural view of touch electrodes and touch wires of an in-cell touch display panel in a prior art.

FIG. 2 is a structural view A of touch electrodes and touch wires of an array substrate according to a first embodiment of the present disclosure.

FIG. 3 is a structural view B of touch electrodes and touch wires of an array substrate according to a first embodiment of the present disclosure.

FIG. 4 is a structural view C of touch electrodes and touch wires of an array substrate according to a first embodiment of the present disclosure.

FIG. 5 is a structural view of touch electrodes and touch wires of an array substrate according to a second embodiment of the present disclosure.

FIG. 6 is a structural view A of touch electrodes and touch wires of an array substrate according to a third embodiment of the present disclosure.

FIG. 7 is a structural view B of touch electrodes and touch wires of an array substrate according to a third embodiment of the present disclosure.

FIG. 8 is a structural view of touch electrodes and touch wires of an array substrate according to a fourth embodiment of the present disclosure.

FIG. 9 is a structural view A of touch electrodes and touch wires of an array substrate according to a fifth embodiment of the present disclosure.

FIG. 10 is a structural view B of touch electrodes and touch wires of an array substrate according to a fifth embodiment of the present disclosure.

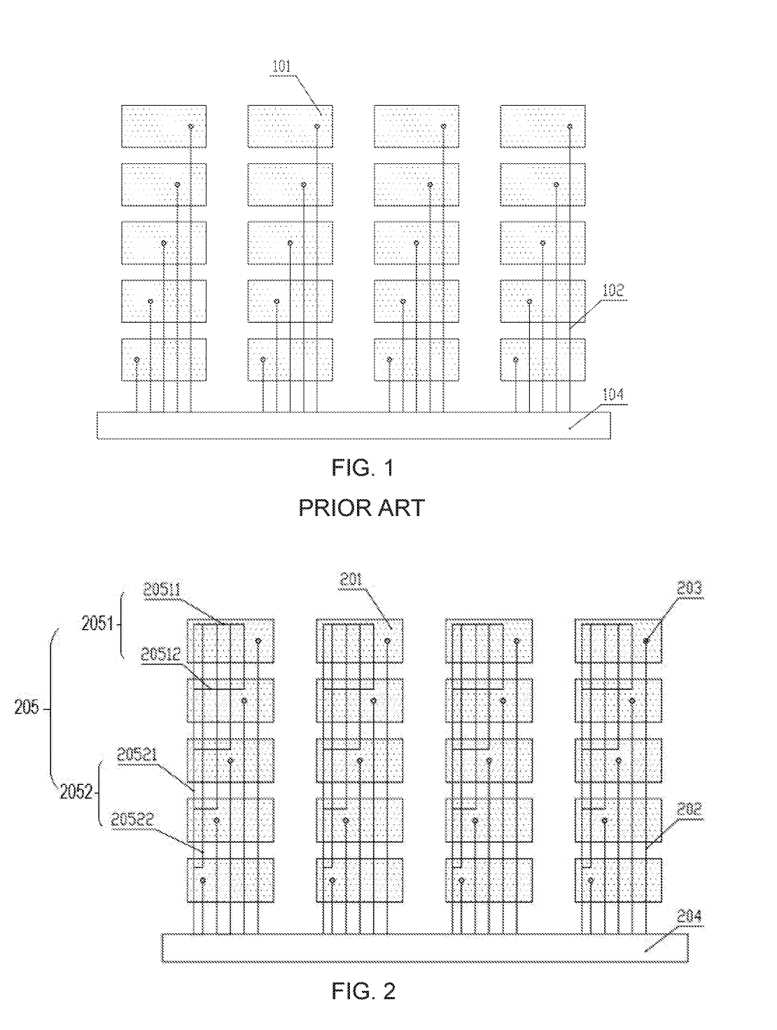

### DETAILED DESCRIPTION OF PREFERRED EMBODIMENTS

The foregoing objects, features, and advantages adopted by the present disclosure can be best understood by referring to the following detailed description of the preferred embodiments and the accompanying drawings. Furthermore, the directional terms described in the present disclosure, such as upper, lower, front, rear, left, right, inside, outer, side, etc., are only directions with reference to the accompanying drawings, so that the used directional terms are used to describe and understand the present disclosure, but the present disclosure is not limited thereto. In the drawings, units with similar structures use the same numerals.

### Embodiment 1

As shown in FIG. 2, the present disclosure provides an array substrate, wherein the array substrate includes a first common electrode layer, a pixel electrode layer, and wires.

The first common electrode layer is patterned to form at least two first common electrode plates 201 arranged in an array. In this embodiment of the present disclosure, the first common electrode plates arranged in an array of 4×5 are taken as an example for brief description.

Each first common electrode plate 201 is a common electrode, and is also as a touch control electrode. When a display panel is in a display state, the first common electrode plates 201 of the first common electrode layer and the pixel electrode layer are used to drive liquid crystals. The wires are used to be provided with a first voltage to eliminate an interference of an electric field on the liquid crystals corresponding to gaps. When the display panel is in a touch state, the first common electrode plates 201 of the first common electrode layer is used to output a touch signal according to a touch operation.

In the present disclosure, the wires include first wires 202 and second wires 205, and the first wires 202 and the second wires 205 are manufactured in one same mask, and the first wires 202 and the second wires 205 do not intersect each other.

Gaps are formed between corresponding two of the first common electrode plates 201 adjacent to each other, and the gaps include horizontal gaps and vertical gaps. A horizontal gap is shielded by a horizontal light shielding strip, and a vertical gap is shielded by a vertical light shielding strip, wherein, the first wires 202 and the second wires 205 are disposed above or below the horizontal gaps, the vertical gaps, or the first common electrode plates 201.

Furthermore, the first wires 202 and the first common electrode plates 201 correspond one-to-one. As shown in FIG. 2, the array substrate includes a plurality of columns of the first common electrode plates 201, and each column of the common electrode plates 201 includes five of the first common electrode plates 201. That is, each column of the first common electrode plates 201 includes five of the first wires 202. One end of each of the first wires 202 is connected to one of the first common electrode plates 201 through a via 203, and the other end of each of the first wires 202 is connected to a touch chip 204 of the array substrate.

The second wires 205 are formed above or below the first common electrode plates 201. The second wires 205 include horizontal second wires 2051 and vertical second wires 2052. The horizontal second wires 2051 include type I wires 20511 and type II wires 20512, and the vertical second wires 2052 include type III wires 20521 and type IV wires 20522.

The number of the horizontal second wires 2051 or the vertical second wires 2052 is equal to the number of the first common electrode plates 201 in each column. Furthermore, each of the horizontal second wires 2051 is electrically connected to a type III wire 20521 in a vertical direction, and each of the vertical second wires 2052 is electrically connected to a type III wire 20521 in a horizontal direction.

As shown in FIG. 2, the second wires 205 include a plurality of horizontal second wires 2051 and a plurality of vertical second wires 2052. The plurality of horizontal second wires 2051 or the plurality of vertical second wires 2052 are arranged side by side. Each of the horizontal second wires 2051 or each of the vertical second wires 2052 has a different length, and is reduced or increased in steps.

In this embodiment, a type I wire in a horizontal direction is located over a first common electrode plate, which is far away from the touch chip 204, in a certain column. The type I wire 20511 is the longest wire among the five horizontal second wires 2051. Each of the vertical second wires 2052 is connected to the type I wire 20511. A type III wire 20521 in a vertical direction is the longest wire of the five vertical second wires 2052, and the type III wire is connected to each of the horizontal second wires 2051, and one end of the type III wire 20521 is connected to the type I wire 20511, and the other end of the type III wire 20521 is connected to the touch chip 204. The positions of the horizontal second wires 2051 and the vertical second wires 2052 are not limited to the above-mentioned positions, and can be reasonably arranged according to the arrangement of the first wires 202.

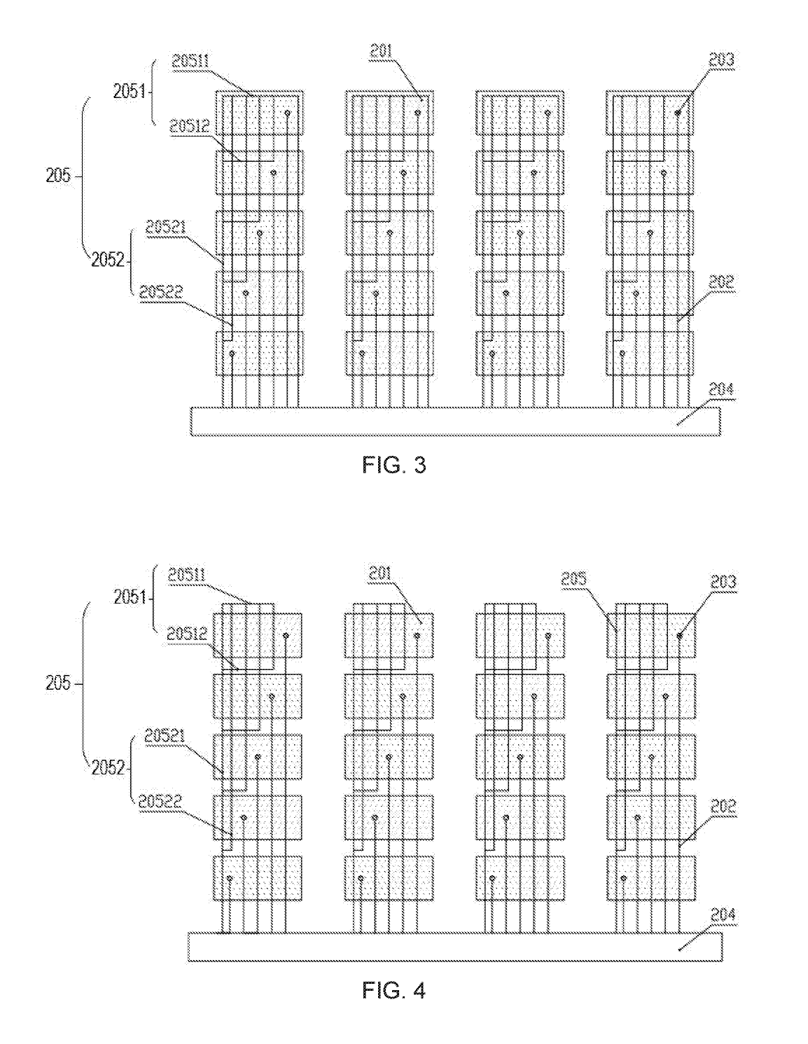

As shown in FIG. 3, compared with FIG. 2, in this embodiment, each column of the first common electrode plates 201 includes two longer type III wires 20521, and one end of each of the two type III wires 20521 is connected to the type I wire 20511, and the other end of each of the two type III wires 2052 is connected to the touch chip 204.

As shown in FIG. 4, compared with FIG. 2, in this embodiment, a type IV wire 20522 is not disposed over each column of the first electrode plates 201, and each of the horizontal second wires 2051 is disposed over a vertical gap between two of the first electrode plates adjacent to each other, so as to stop the influence of the voltage on gate lines for the liquid crystal molecules.

Furthermore, in FIG. 2 to FIG. 4, the connection manner of the first wires 202 can be adjusted to a certain extent. For example, the first to fifth of the first wires 202 over each column can be arranged using permutation and combination, and the corresponding horizontal second wires 205 and the vertical second wires 205 also need to be adjusted accordingly.

### Embodiment 2

This embodiment is the same or similar to the above-mentioned embodiment 1, but the differences are that:

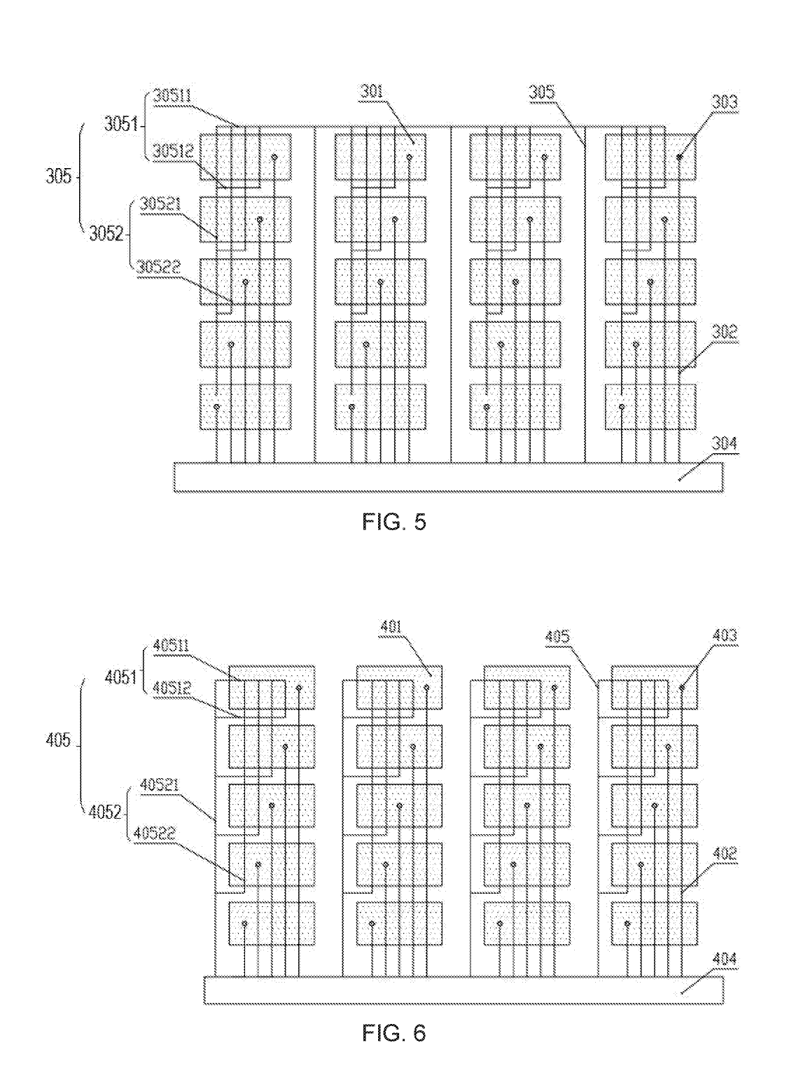

As shown in FIG. 5, in this embodiment, a type I wire 30511 is formed over a horizontal boundary of the first common electrode layer which is far away from the touch chip 304. A type III wire 30521 is disposed over a vertical gap between two of the first common electrode plates 301 adjacent to each other. The type III wire 30521 electrically connect the type I wire 30511 with the touch chip 304 together. Furthermore, a type II wire 30512 is disposed over a horizontal gap between two of the first common electrode plates adjacent to each other.

### Embodiment 3

This embodiment is the same or similar to the above-mentioned embodiment 1 or embodiment 2, but the differences are that:

As shown in FIG. 6, in this embodiment, type III wires 40521 are disposed on both sides of each column of the first common electrode plates 401. A type III wire 40521 corresponds to the vertical gap of the two columns of the first common electrode plates adjacent to each other or is on the outside of the first common electrode layer. Each horizontal second wire 4051 is connected with the type III wire 40521, and each type IV wire 40522 is connected with the same type I wire 40511. The type III wire 40521 in the horizontal direction is disposed over the horizontal gap between two columns of the common electrode plates adjacent to each other. A type I wire 40511 which is farthest from the touch chip 404 is disposed over each column of the first common electrode plates or on the outside of the first common electrode layer.

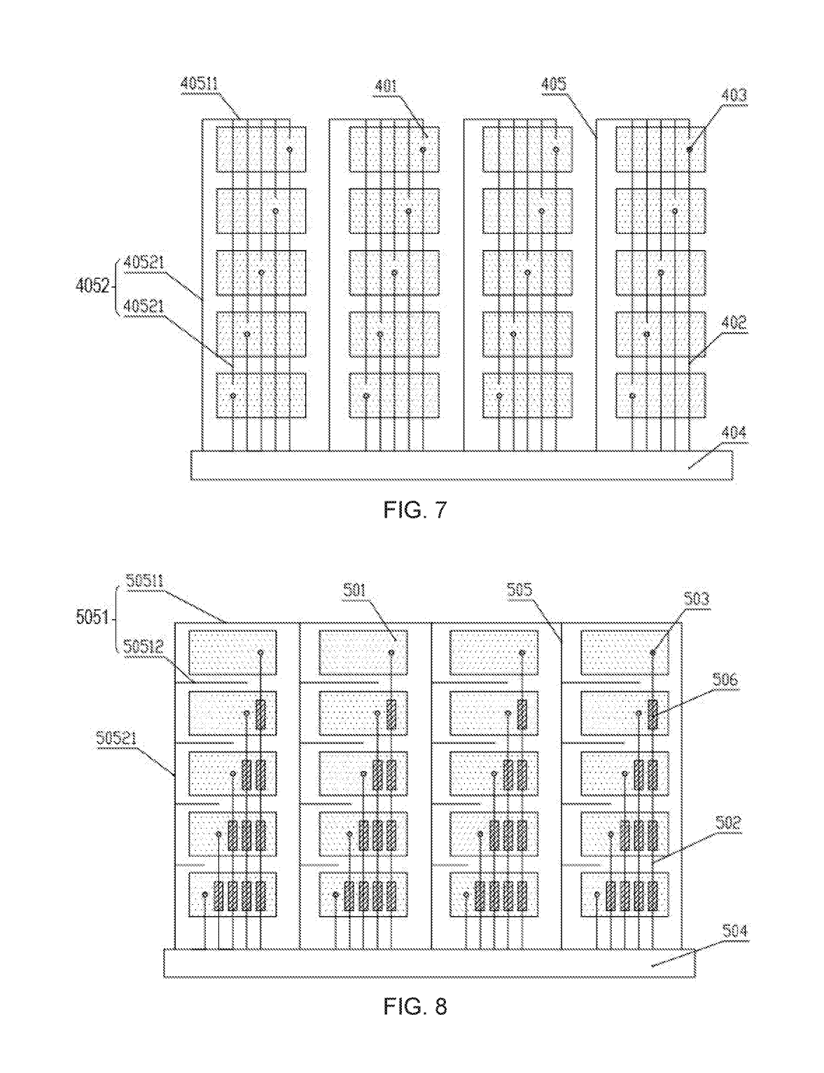

As shown in FIG. 7, compared with FIG. 6, the type II wires 40512 located over corresponding horizontal gaps between two first common electrode plates 401 adjacent to each other are removed from the present disclosure. The type I wire 40511 is disposed on the outside of each column of the first common electrode plates 401.

### Embodiment 4

This embodiment is the same or similar to the above-mentioned first embodiment to the third embodiment, but the differences are that:

As shown in FIG. 8, in this embodiment, the type IV wire 50522 located over the first common electrode plates in the vertical direction is removed, and only the type III wire 50521 in the vertical gap between the two columns of the first common electrode plates adjacent to each other or on the outer side of the first common electrode layer is provided. Furthermore, in the horizontal direction, a horizontal second wire 5051 connected to each type III wire 50521 on the outside of the first common electrode layer is provided. Furthermore, the type II wire 50512 with a short length is disposed over the horizontal gap of each column of the common electrode plates, and the type II wire 50512 of each column of the first common electrode plates is connected to the same type III wire 50521.

Furthermore, in the first embodiment to the fourth embodiment of the present disclosure, since the second wire 505 disposed over the first common electrode plate 501 has a certain electric potential, the second wire 505 and the first common electrode plate 501 can form a capacitance to influence the touch effect of the display screen. Therefore, commonly, an insulating layer is disposed between the second wire and the first common electrode plate 501, and in order to reduce the technical difficulty in this process, each vertical second wire 5052 and each first wire 502 are disposed along the same vertical line, but are not limited to the position.

As shown in FIG. 8, the present disclosure can further provide a recess 506 in each of the first common electrode plates 501 under each first wire. That is, the first common electrode plate 501 is hollowed out in this position to reduce a coupling capacitance between each first wire 502 and the first common electrode plate, namely to reduce a touch load of each first wire 502.

### Embodiment 5

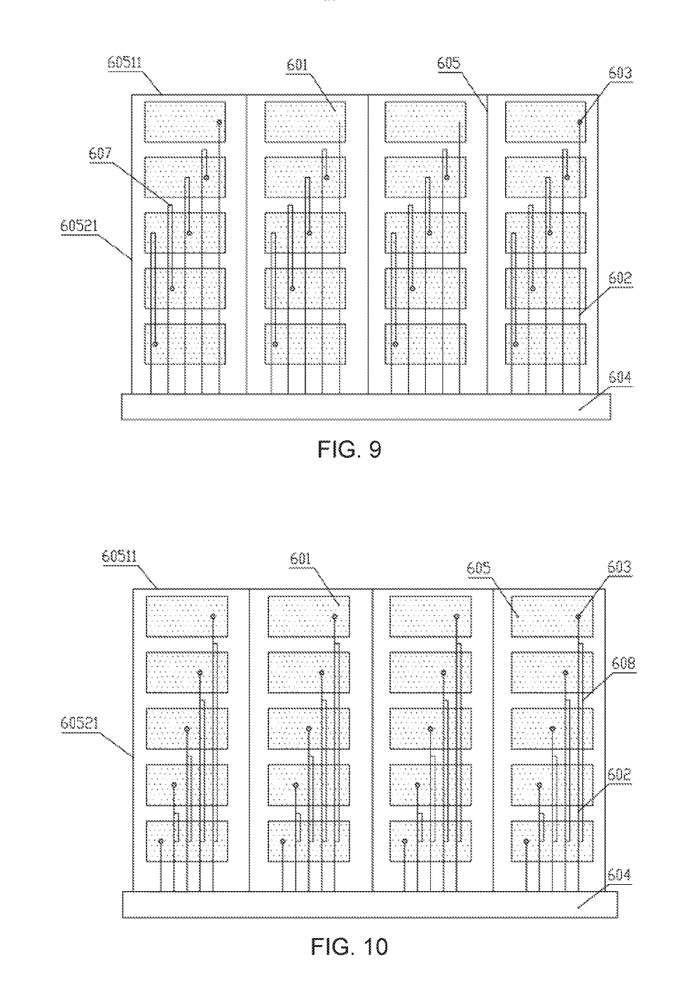

As shown in FIG. 9, in this embodiment, on the basis of the fourth embodiment (the third wires are removed for convenience of description), a portion of the first wires 602 with shorter lengths are added with corresponding U-turn first wires 607, so that lengths of the first wires 602 over each column of the first common electrode plates 601 are the same or similar, and transmission time for each touch signal in the wires are equal or similar. This embodiment mainly increases a resistance value of a first wire 602 until being the same or similar. The resistance value between the longest and the shortest first wire 602 is reduced. The speed of the signal transmission is ensured, and the touch sensitivity is improved.

As shown in FIG. 10, in the present disclosure, some of the first wires 602 has corresponding parallel first wires 608, so that a resistance value of each of the first wires 602 is reduced until being the same or similar, and the resistance value between the longest and the shortest first wire 602 is reduced. The speed of the signal transmission is ensured, and the touch sensitivity of the display panel is improved.

In the above-mentioned embodiments, the position where the second wire is disposed over is not limited to a horizontal gap or a vertical gap, but the second wire is possible to be disposed at any position above or below the first common electrode plate. The direction of the second wire is not limited to the horizontal direction or vertically direction.

Furthermore, the connection manner of the second wires over the two columns of the first common electrode plates adjacent to each other is the same. An insulating layer is disposed between the first common electrode plate and the first wire, or the second wire.

The present disclosure further provides a display panel, wherein the display panel includes the array substrates.

In the first embodiment to the fifth embodiment of the present disclosure, an in-cell touch method based on a fringe field effect display mode is mainly described as an example. However, the present disclosure is not limited to this display mode. The present disclosure can also be applied to other liquid crystal mode display or other type of displays.

The present disclosure provides an array substrate and a display panel. The array substrate includes a first common electrode layer, a pixel electrode layer, and wires. The first common electrode layer includes at least two first common electrode plates, and gaps are formed between corresponding two of the first common electrode plates adjacent to each other. The wires are located on one side of the first common electrode layer, and the wires are disposed corresponding to the gaps. The wires are used to be provided with a first voltage to eliminate an interference of the electric field on the liquid crystals corresponding to the gaps, so as to improve the display effect of the display panel. Furthermore, parallel or U-turn first wires are provided, so that the resistance value of each first wire is equal or similar, thereby improving the touch sensitivity of the display panel.

The present disclosure has been described with preferred embodiments thereof and it is understood that many changes and modifications to the described embodiment can be carried out without departing from the scope and the spirit of the present disclosure that is intended to be limited only by the appended claims.

What is claimed is:

1. An array substrate, comprising:
a first common electrode layer comprising at least two first common electrode plates, wherein gaps are formed between corresponding two of the first common electrode plates adjacent to each other;
a pixel electrode layer disposed opposite to the first common electrode layer; and
wires located on one side of the first common electrode layer, wherein the wires are disposed corresponding to the gaps;
wherein the wires comprise first wires and second wires; the gaps comprise horizontal gaps and vertical gaps; the first wires and the second wires are disposed above or below the horizontal gaps, the vertical gaps, or the first common electrode plates;
wherein, when a display panel is in a display state, the first common electrode plates of the first common electrode layer and the pixel electrode layer are configured to drive liquid crystals, and the wires are configured to be provided with a first voltage to eliminate an interference of an electric field on the liquid crystals corresponding to the gaps; and when the display panel is in a touch state, the first common electrode plates of the first common electrode layer are configured to output a touch signal according to a touch operation.

2. The array substrate according to claim 1, wherein the first wires and the second wires are manufactured in one same mask, and the first wires and the second wires do not intersect each other; and
one end of one of the first wires is connected to one of the first common electrode plates through a via, and the other end of the one of the first wires is connected to a touch chip of the display panel.

3. The array substrate according to claim 1, wherein a recess is disposed in one of the first common electrode plates corresponding to one of the first wires or one of the second wires.

4. The array substrate according to claim 1, wherein the second wires comprise horizontal second wires and vertical second wires; and
the number of the horizontal second wires or the vertical second wires is equal to the number of the first common electrode plates in each of columns of the first common electrode plates.

5. The array substrate according to claim 4, wherein each of the horizontal second wires is electrically connected to one of the vertical second wires, and each of the vertical second wires is electrically connected to one of the horizontal second wires.

6. The array substrate according to claim 4, wherein each of the horizontal second wires over each of the columns of the first common electrode plates is electrically connected to one of the vertical second wires, and each of the vertical second wires over each of the columns of the first common electrode plates is electrically connected to one of the horizontal second wires.

7. The array substrate according to claim 1, wherein a portion of the first wires has corresponding U-turn first wires, and a total length of each of the first wires is equal to each other.

8. The array substrate according to claim 1, wherein a portion of the first wires has corresponding parallel first wires, and a resistance of each of the first wires is equal to each other.

9. A display panel comprising the array substrate according to claim 1.

10. An array substrate, comprising:
a first common electrode layer comprising at least two first common electrode plates, wherein gaps are formed between corresponding two of the first common electrode plates adjacent to each other;
a pixel electrode layer disposed opposite to the first common electrode layer; and
wires located on one side of the first common electrode layer, wherein the wires are disposed corresponding to the gaps;
wherein, when a display panel is in a display state, the first common electrode plates of the first common electrode layer and the pixel electrode layer are configured to drive liquid crystals, and the wires are configured to be provided with a first voltage to eliminate an interference of an electric field on the liquid crystals corresponding to the gaps; and when the display panel is in a touch state, the first common electrode plates of the first common electrode layer are configured to output a touch signal according to a touch operation.

11. The array substrate according to claim 10, wherein the wires comprise first wires and second wires;
the first wires and the second wires are manufactured in one same mask, and the first wires and the second wires do not intersect each other; and
one end of one of the first wires is connected to one of the first common electrode plates through a via, and the other end of the one of the first wires is connected to a touch chip of the display panel.

12. The array substrate according to claim 11, wherein the second wires comprise horizontal second wires and vertical second wires; and
the number of the horizontal second wires or the vertical second wires is equal to the number of the first common electrode plates in each of columns of the first common electrode plates.

13. The array substrate according to claim 12, wherein each of the horizontal second wires is electrically connected to one of the vertical second wires, and each of the vertical second wires is electrically connected to one of the horizontal second wires.

14. The array substrate according to claim 12, wherein each of the horizontal second wires over each of the columns of the first common electrode plates is electrically connected to one of the vertical second wires, and each of the vertical second wires over each of the columns of the first common electrode plates is electrically connected to one of the horizontal second wires.

15. The array substrate according to claim 11, wherein a portion of the first wires has corresponding U-turn first wires, and a total length of each of the first wires is equal to each other.

16. The array substrate according to claim 11, wherein a portion of the first wires has corresponding parallel first wires, and a resistance of each of the first wires is equal to each other.
